(19) United States
(12) Patent Application Publication
(10) Pub. No.: US 2025/0159951 A1
(43) Pub. Date: May 15, 2025

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventor: Chih-Yang CHEN, Hsinchu City (TW)

(73) Assignee: TAIWAN SEMICONDUCTOR MANUFACTURING COMPANY, LTD., Hsinchu (TW)

(21) Appl. No.: 18/508,935

(22) Filed: Nov. 14, 2023

(51) Int. Cl. H01L 29/06; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 64/017

(57) ABSTRACT

A method includes forming a first stack of alternating first semiconductor layers and first sacrificial layers over a substrate; forming a second stack of alternating second semiconductor layers and second sacrificial layers over the first stack, wherein the first semiconductor layers and the second semiconductor layers are made of different materials; replacing the first sacrificial layers with third sacrificial layers; removing the second sacrificial layers, such that the second semiconductor layers are suspended over the substrate; after removing the second sacrificial layers, removing the third sacrificial layers, such that the first semiconductor layers are suspended over the substrate; forming a first metal gate structure wrapping around the first semiconductor layers; and forming a second metal gate structure wrapping around the second semiconductor layers.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 18B illustrate a method in various stages of forming a semiconductor device in accordance with some embodiments of the present disclosure.

FIG. 19 is a perspective view of a semiconductor device in accordance with some embodiments of the present disclosure.

FIGS. 20A to 35B illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

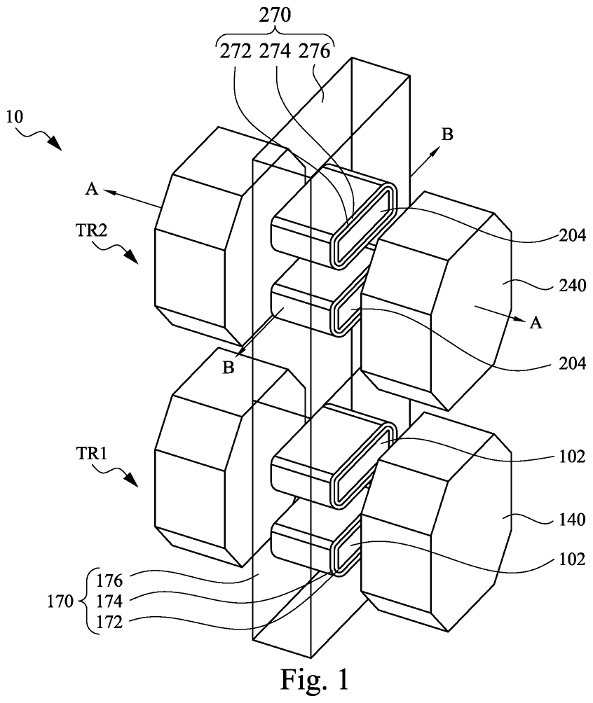

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FET. The first transistor TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, the second transistor TR2 includes second semiconductor channel layers 204 vertically stacked one above another, a second metal gate structure 270 wrapping around each of the second semiconductor channel layers 204, and second source/drain epitaxy structures 240 on opposite ends of each of the second semiconductor channel layers 204. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, the first transistor TR1 has a first conductivity type (e.g., n-type) and the second transistor TR2 has a second conductivity type (e.g., p-type) different from the first conductivity type. In some embodiments, the first transistor TR1 can be referred to as an N-FET, and the second transistor TR2 can be referred to as a P-FET. In some embodiments, the first semiconductor channel layers 102 may include material suitable for N-type device, such as silicon (Si), while the second semiconductor channel layers 204 may include material suitable for P-type device, such as silicon germanium (SiGe).

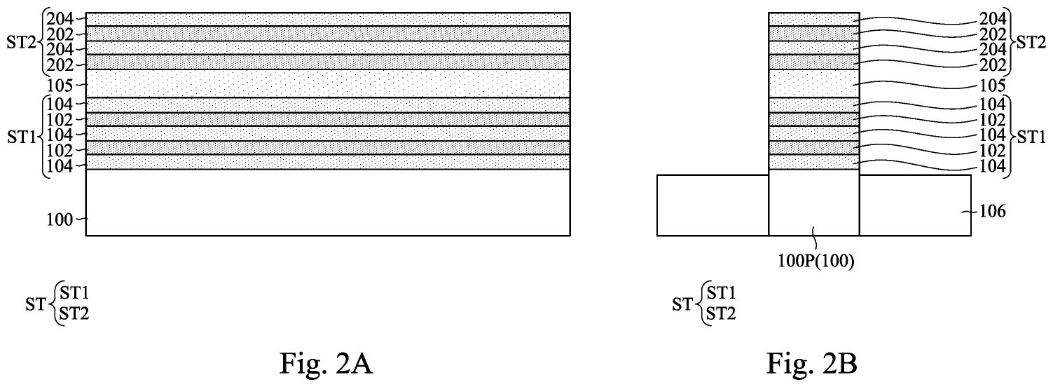

FIGS. 2A to 18B illustrate a method in various stages of forming a semiconductor device in accordance with some embodiments of the present disclosure. In greater detail, FIGS. 2A to 18B illustrate a method for forming a detailed structure of the CFET 10 of FIG. 1. It is noted that FIGS. 2A, 3A, 4A, 5A, 6A, 7A, 8A, 9A, 10A, 11A, 12A, 13A, 14A, 15A, 16A, 17A, 18A include cross-sectional views the same as the cross-sectional view along line A-A of FIG. 1, and FIGS. 2B, 3B, 4B, 5B, 6B, 7B, 8B, 9B, 10B, 11B, 12B, 13B, 14B, 15B, 16B, 17B, 18B include cross-sectional views the same as the cross-sectional view along line B-B of FIG. 1. Although FIGS. 2A to 17B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 17B may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 50 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es).

A patterning process may be performed to the semiconductor stack ST and the substrate 100 to form a fin structure, as shown in FIG. 2B. In some embodiments, the patterning process may include forming a patterned photoresist layer over the stack ST, and then performing an etching process to remove unwanted portions of the semiconductor stack ST and the substrate 100 exposed by the patterned photoresist layer. The fin structure may include a remaining portion of the semiconductor stack ST and a semiconductor strip 100P protruding over the substrate 100. In some embodiments, the etching process may include wet etch, dry etch, or the like.

After the fin structure is formed, isolation structures 106 are formed over the substrate 100 and laterally surrounding the fin structure. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

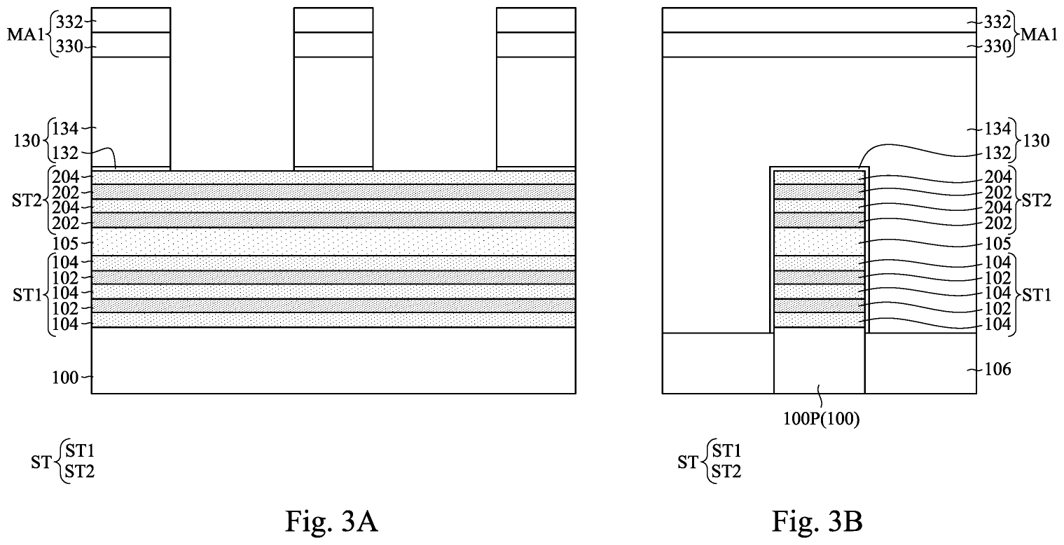

Reference is made to FIGS. 3A and 3B. Dummy gate structures 130 are formed over the substrate 100 and crossing the fin structure. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

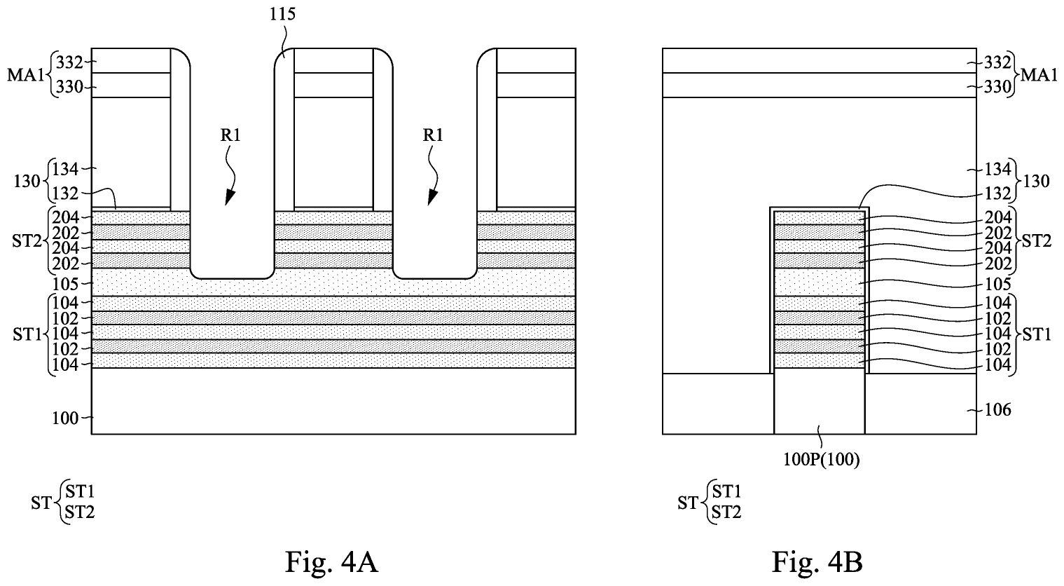

Reference is made to FIGS. 4A and 4B. Gate spacers 115 are formed on opposite sidewalls of each of the dummy gate structures 130. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130. In some embodiments, the remaining vertical portions of the spacer layer on sidewalls of the dummy gate structures 130 can be referred to as gate spacers 115. In some embodiments, the spacer layer may be deposited using techniques such CVD, ALD, or the like.

After the gate spacers 115 are formed, an etching process is performed, by using the gate spacers 115 and the patterned masks MA1 (or the dummy gate structures 130) as etch mask, to remove portions of the second stack ST2. In greater detail, the etching process removes portions of the semiconductor layers 202 and 204, so as to form recesses R1 in the second stack ST2. In some embodiments, the semiconductor layer 105 may include higher etch resistance to the etching process than the semiconductor layers 202 and 204, and thus the semiconductor layer 105 may act as an etch stop layer during the etching process. As a result, the etching process may be stopped at the semiconductor layer 105, and thus the underlying semiconductor layers 102 and 104 are protected by the semiconductor layer 105 and may keep substantially intact after the etching process is complete. In some embodiments, the exposed portions of the semiconductor layer 105 may be slightly etched during the etching process, and thus the bottom surfaces of the recesses R1 may be lower than top surface of the semiconductor layer 105. In some embodiments, the etching process may be wet etch, dry etch, or combinations thereof.

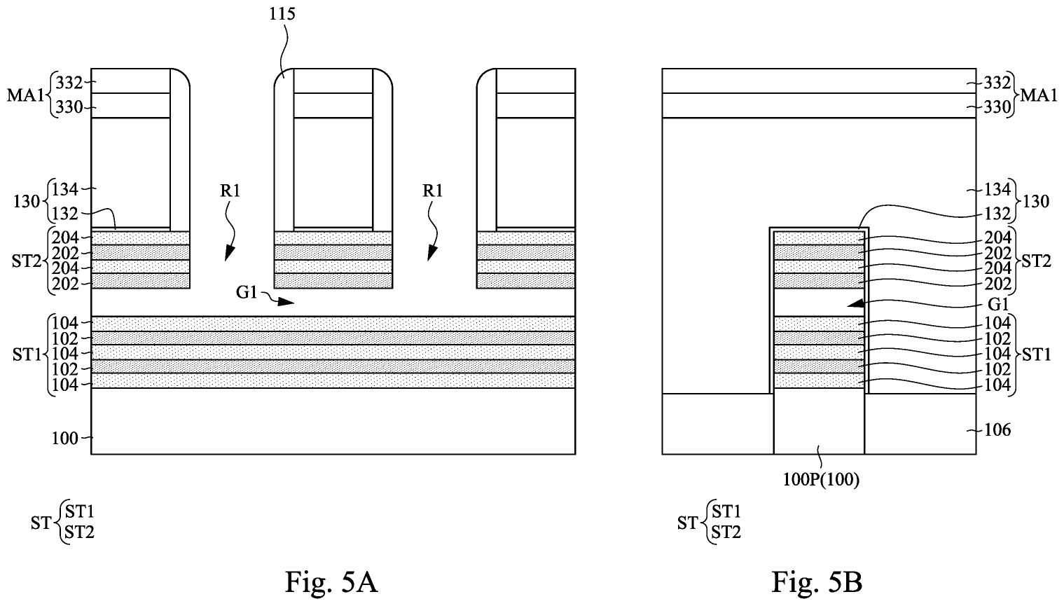

Reference is made to FIGS. 5A and 5B. An etching process is performed to remove the semiconductor layer 105 through the recesses R1. As a result, gaps G1 may be formed between the first stack ST1 and the second stack ST2. In greater detail, each of the gaps G1 is vertically between the topmost semiconductor layer 104 and the bottommost semiconductor layer 202. In some embodiments, the semiconductor layers 102, 104, 202, and 204 may include higher etch resistance to the etching process than the semiconductor layer 105, and thus the semiconductor layers 102, 104, 202, and 204 may keep substantially intact after the etching process is complete. In some embodiments, the etching process may be wet etch, dry etch, or combinations thereof.

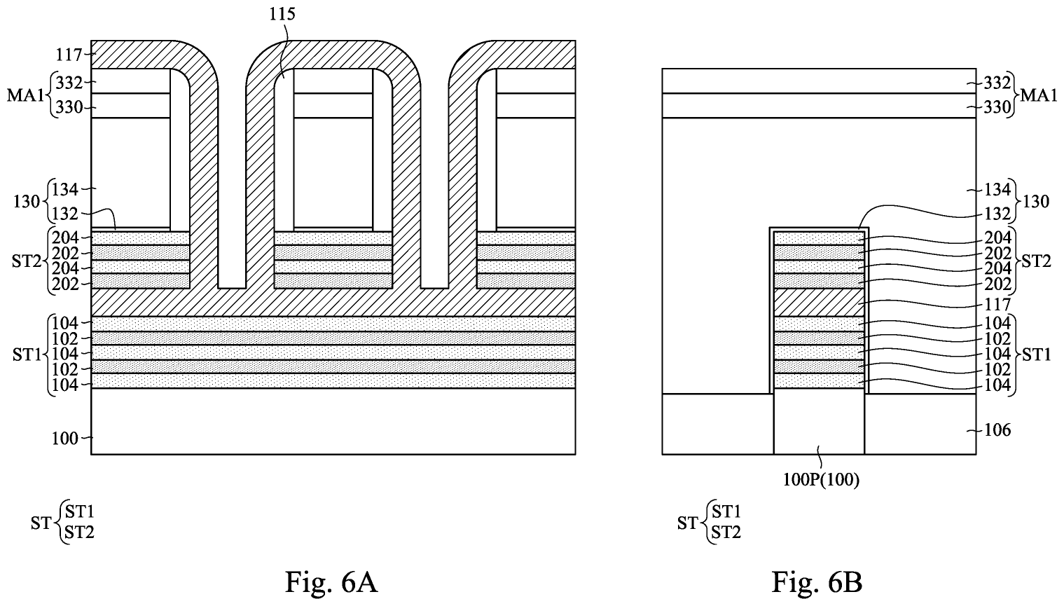

Reference is made to FIGS. 6A and 6B. An isolation layer 117 is deposited blanket over the substrate 100 and filling the gaps G1. The isolation layer 117 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

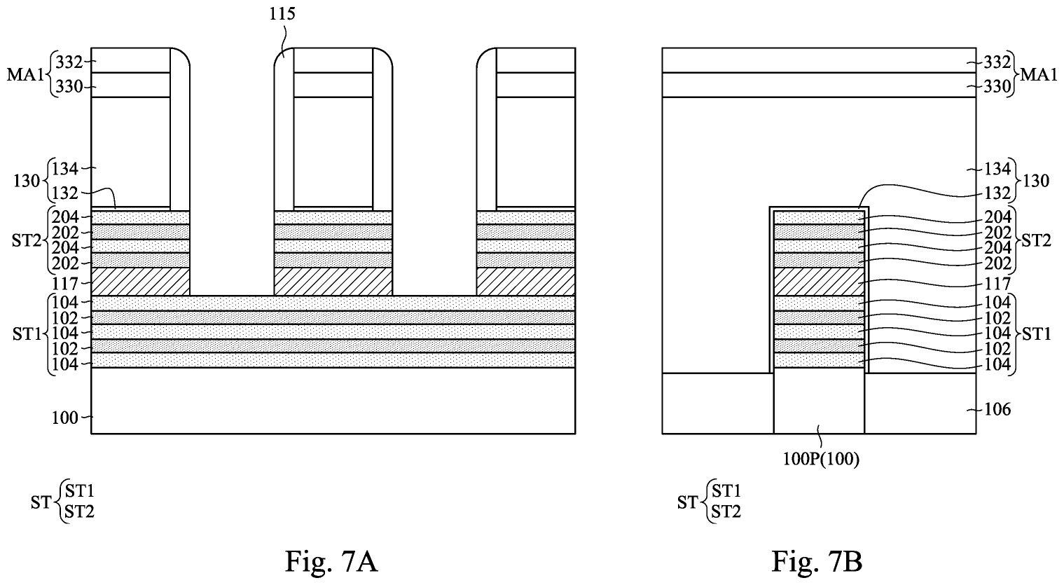

Reference is made to FIGS. 7A and 7B. An anisotropic etching process is performed to remove portions of the isolation layer 117 outside the gaps G1, and the remaining portions of the isolation layer 117 are present between the topmost semiconductor layer 104 and the bottommost semiconductor layer 202. As a result, the portion of the semiconductor layer 105 (see FIGS. 4A and 4B) between the topmost semiconductor layer 104 and the bottommost semiconductor layer 202 is replaced with the isolation layer 117.

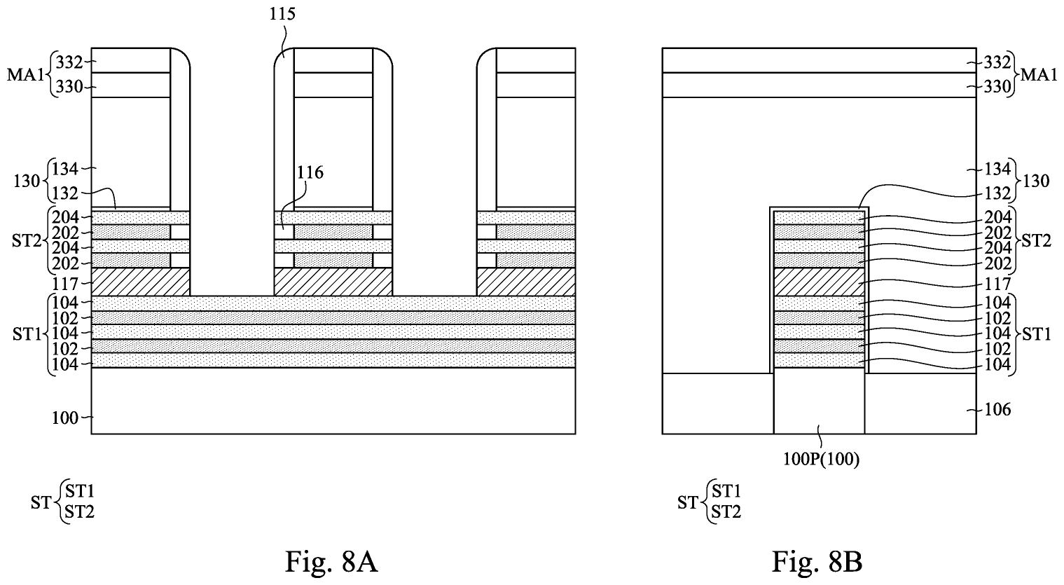

Reference is made to FIGS. 8A and 8B. The semiconductor layers 202 are laterally etched to form sidewall recesses. Then, inner spacers 116 are formed in the sidewall recesses on opposite ends of each of the semiconductor layers 202. In some embodiments, the inner spacers 116 may be formed by, for example, depositing an inner spacer layer blanket over the substrate 100 and filling the sidewall recesses on opposite sides of the semiconductor layers 202, and then performing an anisotropic etching to remove portions of the inner spacer layer outside the sidewall recesses, leaving the remaining portions of the inner spacer layer in the sidewall recesses as the inner spacers 116. The inner spacers 116 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized. In some embodiments, although the semiconductor layers 102 may include a same material as the semiconductor layers 202, the topmost semiconductor layer 104 may protect the semiconductor layers 102 during etching the semiconductor layers 202.

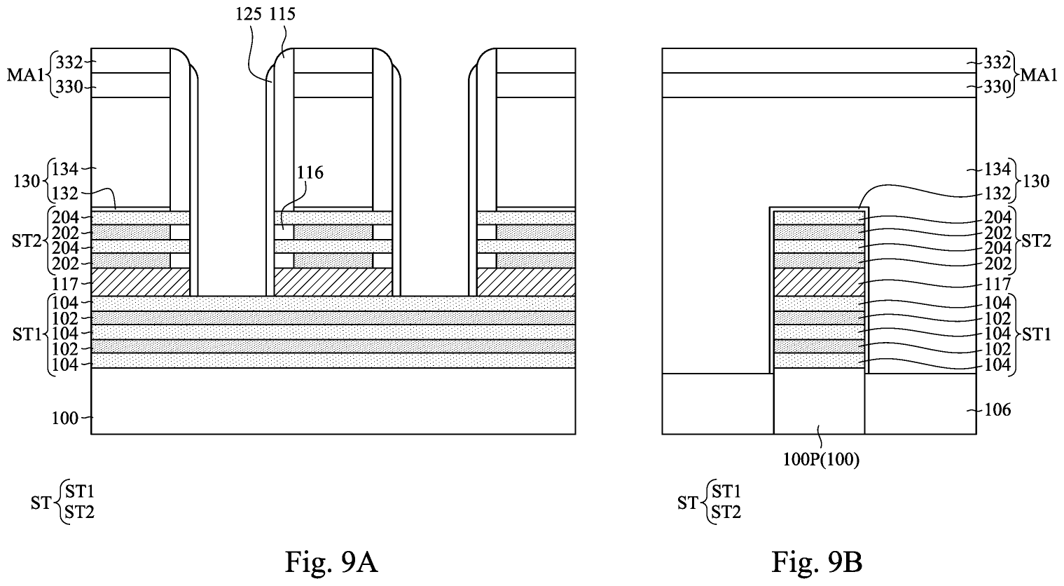

Reference is made to FIGS. 9A and 9B. Liners 125 are formed lining sidewall surfaces of the semiconductor layers 204. The liners 125 may also cover the sidewalls of the gate spacers 115, the inner spacers 116, and the isolation layer 117. In some embodiments, the liners 125 may be formed by, for example, depositing a liner layer blanket over the substrate, an anisotropic etching process is performed to remove horizontal portions of the liner layer, such that vertical portions of the liner layer remain on sidewalls of the semiconductor layers 204, the gate spacers 115, the inner spacers 116, and the isolation layer 117. In some embodiments, the remaining vertical portions can be referred to as the liners 125. In some embodiments, the liners 125 may be made of SiN, metal oxide, or other suitable material. In some embodiments, bottommost ends of the liners 125 may be substantially level with bottom surface of the isolation layer 117.

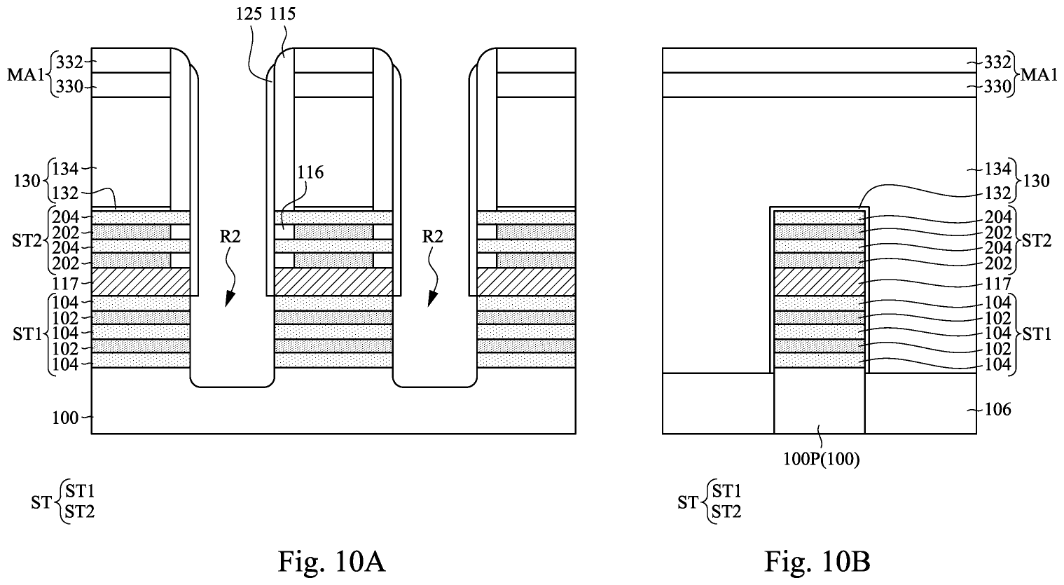

Reference is made to FIGS. 10A and 10B. An etching process is performed, by using the liners 125, the gate spacers 115, and the patterned masks MA1 (or the dummy gate structures 130) as etch mask, to remove portions of the first stack ST1. In greater detail, the etching process removes portions of the semiconductor layers 102 and 104, so as to form recesses R2 in the first stack ST1. In some embodiments, the liners 125 may protect the semiconductor layers 204 during the etching process, and thus the semiconductor layers 204 may keep substantially intact after the etching process is complete. In some embodiments, the exposed portions of the substrate 100 may be slightly etched during the etching process, and thus the bottom surfaces of the recesses R2 may be lower than top surface of the substrate 100. In some embodiments, the etching process may be wet etch, dry etch, or combinations thereof.

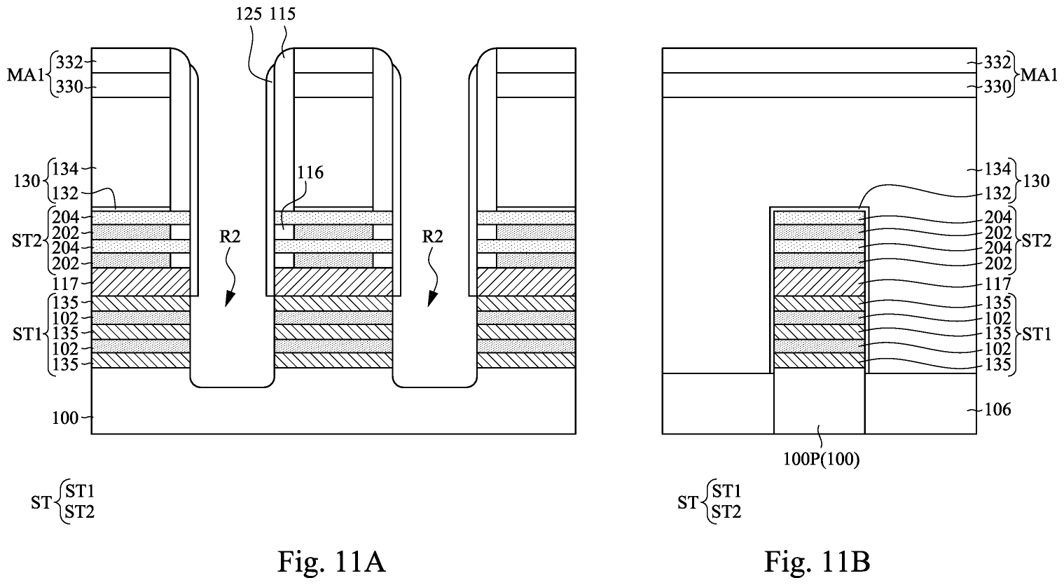

Reference is made to FIGS. 11A and 11B. The semiconductor layers 104 are replaced with dielectric layers 135. In some embodiments, the dielectric layers 135 may include oxide, such as silicon oxide (SiO₂). The dielectric layers 135 may include different dielectric materials than the isolation layer 117 to provide sufficient etching selectivity. The dielectric layers 135 may be formed by, for example, performing an etching process through the recesses R2 to remove the semiconductor layers 104 and to form gaps over and under each of the semiconductor layers 102, depositing a dielectric material within the recesses R2 and filling the gaps, and then performing another etching process to remove the dielectric material outside the gaps, leaving the remaining portions of the dielectric material within the gaps as the dielectric layers 135. In some embodiments, the semiconductor layers 104 can be referred to as sacrificial layers.

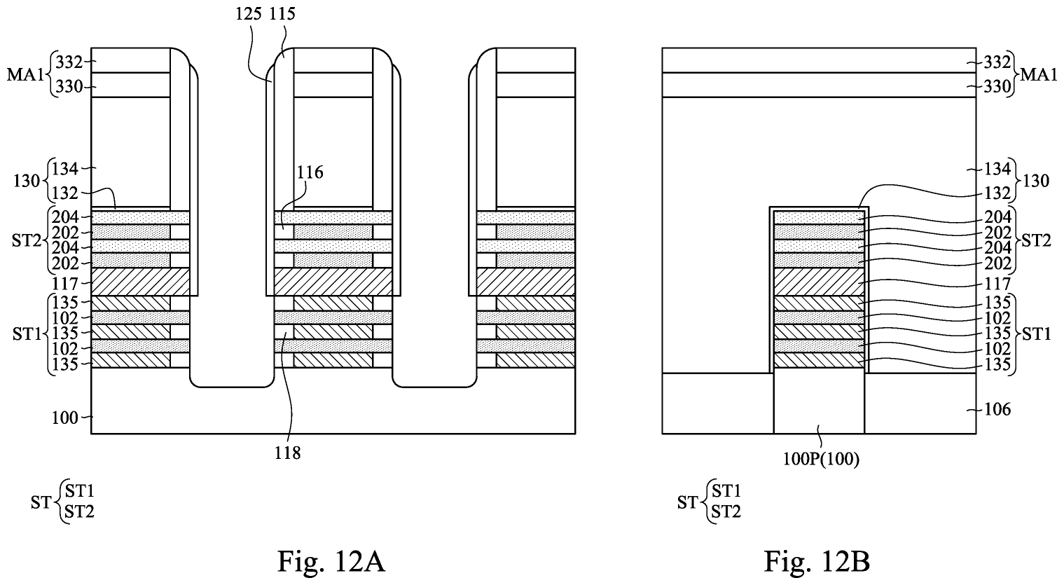

Reference is made to FIGS. 12A and 12B. The dielectric layers 135 are laterally etched to form sidewall recesses. Then, inner spacers 118 are formed in the sidewall recesses on opposite ends of each of the dielectric layers 135. In some embodiments, the inner spacers 118 may be formed by, for example, depositing an inner spacer layer blanket over the substrate 100 and filling the sidewall recesses on opposite sides of the dielectric layers 135, and then performing an anisotropic etching to remove portions of the inner spacer layer outside the sidewall recesses, leaving the remaining portions of the inner spacer layer in the sidewall recesses as the inner spacers 118. The inner spacers 118 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized. In some embodiments, because the inner spacers 116 and 118 are formed at different time points, the inner spacers 116 and 118 may include different materials.

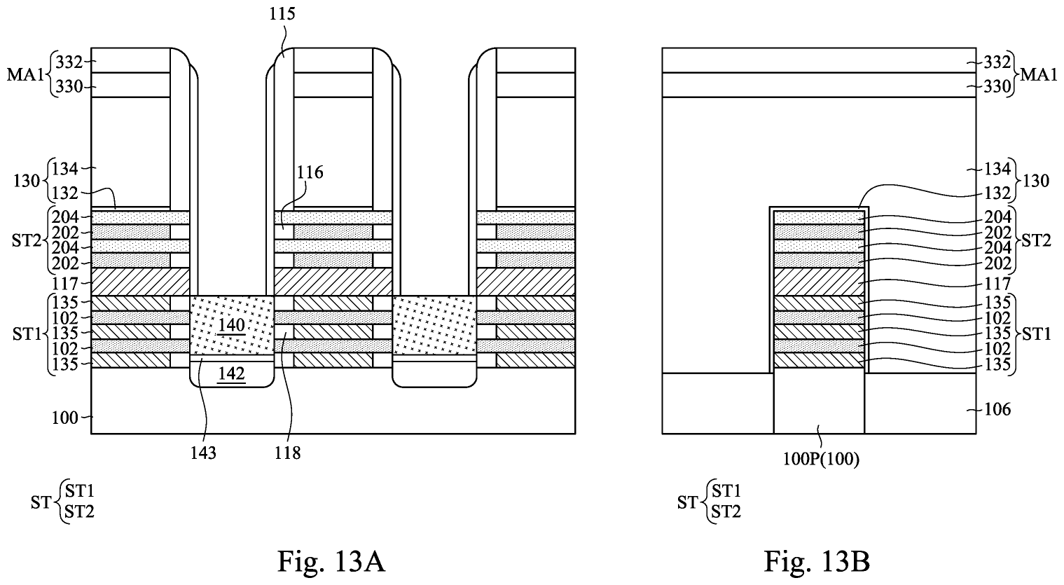

Reference is made to FIGS. 13A and 13B. Epitaxy layers 142 are formed at bottoms of the recesses R2, dielectric layers 143 are formed over the epitaxy layers 142, and then first source/drain epitaxy structures 140 are formed over the dielectric layers 143 and in contact with opposite ends of the semiconductor layers 102. In some embodiments, the formation of the epitaxy layers 142 may include a plurality of deposition cycles, in which each deposition cycle may include a selective epitaxial growth (SEG) process and an etching process. The dielectric layers 143 may be formed by depositing a dielectric material in the recesses R2 and then etching back the dielectric material. The first source/drain epitaxy structures 140 may be formed by suitable deposition process, such as a selective epitaxial growth (SEG) process. In some embodiments, the SEG process may selectively grow a semiconductor material on exposed semiconductor surfaces, such as the exposed surfaces of the epitaxy layers 142 and the exposed surfaces of the semiconductor layers 102. In some embodiments, the first source/drain epitaxy structures 140 may include SiAs, SiP, or combination of SiAs and SiP. In some embodiments, an implantation process may be performed to the first source/drain epitaxy structures 140. For example, the implantation process may include n-type dopants, such as phosphorus (P), arsenic (As), or antimony (Sb), or the like, such that the first source/drain epitaxy structures 140 are n-type epitaxy structures. In some embodiments, the epitaxy layers 142 may be formed without performing an implantation process, and thus the epitaxy layers 142 are un-doped. In some embodiments, the dielectric layers 143 are made of silicon nitride (SiN). The dielectric layers 143 may reduce current leakage from the first source/drain epitaxy structures 140 to the substrate 100.

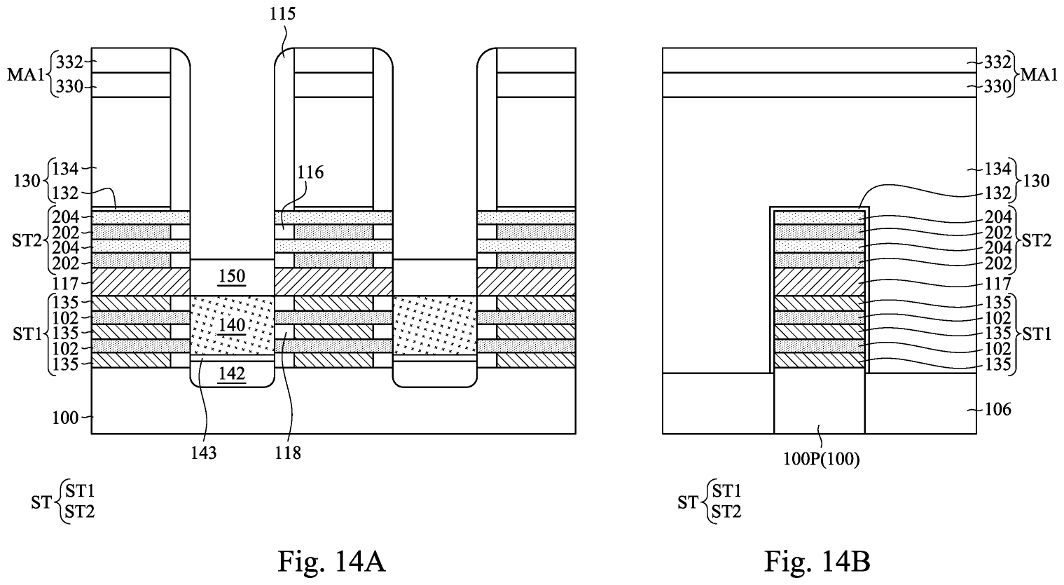

Reference is made to FIGS. 14A and 14B. The liners 125 are removed by using suitable etching process, such that sidewalls of the semiconductor layers 204 are exposed. Then, isolation structures 150 are formed over the first source/drain epitaxy structures 140, respectively. The isolation structures 150 may be formed by, for example, depositing dielectric material(s) over the first source/drain epitaxy structures 140, and then etching back the dielectric material(s). In some embodiments, the isolation structures 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

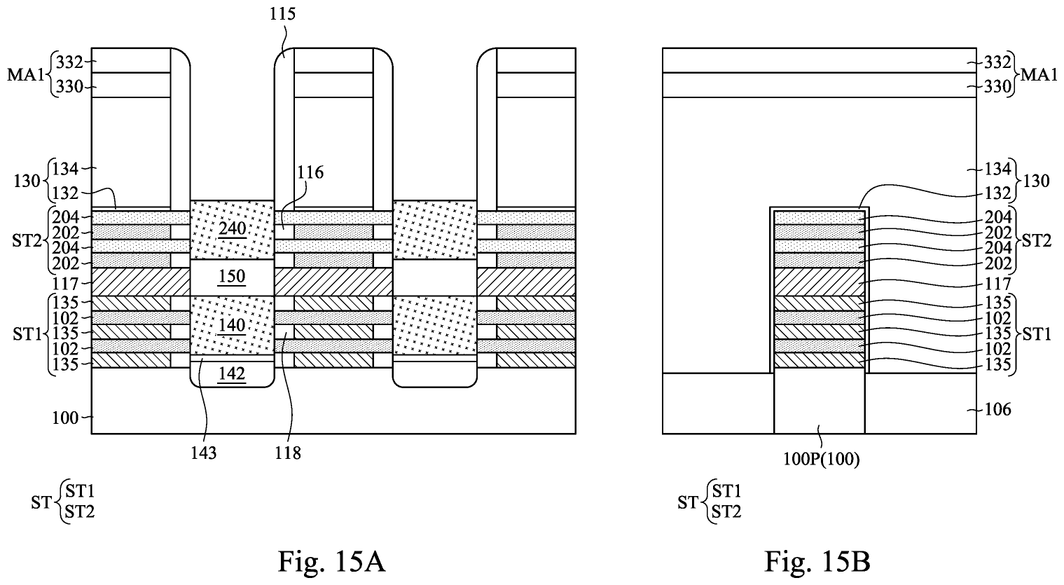

Reference is made to FIGS. 15A and 15B. Second source/drain epitaxy structures 240 are formed on opposite ends of each of the semiconductor layers 204. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the semiconductor layers 204. In some embodiments, the second source/drain epitaxy structures 240 may include SiB, SiGe, or combination of SiB and SiGe. In some embodiments, an implantation process may be performed to the second source/drain epitaxy structures 240. For example, the implantation process may include p-type dopants, such as boron (B), gallium (Ga), indium (In), aluminium (Al), or the like, such that the second source/drain epitaxy structures 240 are p-type epitaxy structures.

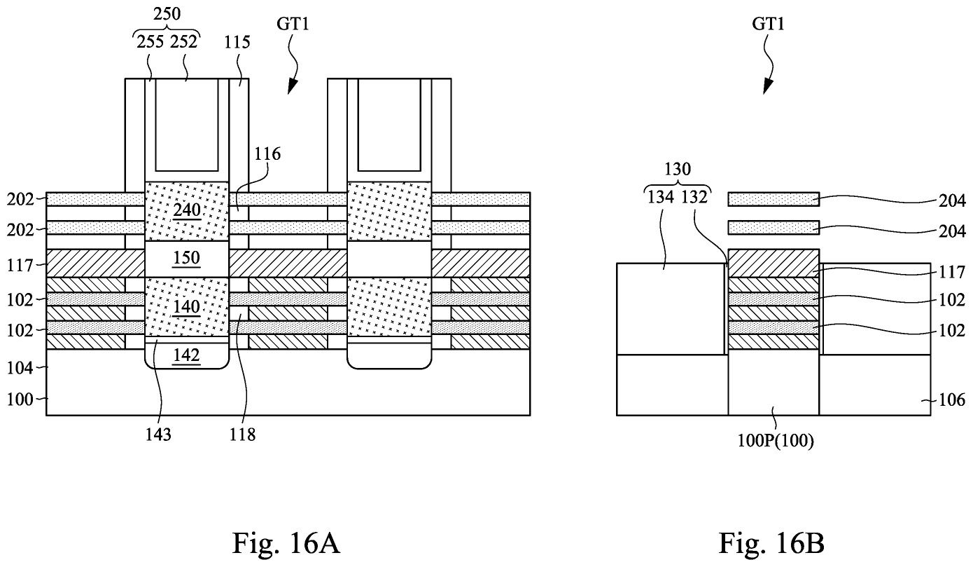

Reference is made to FIGS. 16A and 16B. Isolation structures 250 are formed over the second source/drain epitaxy structures 240, respectively. Each of the isolation structures 250 may include a contact etch stop layer (CESL) 255 and an interlayer dielectric (ILD) layer 252 over the CESL 255. The isolation structures 250 may be formed by, for example, depositing dielectric material(s) over the second source/drain epitaxy structures 240, and then performing a planarization process, such as CMP, to remove excess dielectric material(s). In some embodiments, during the planarization process, the patterned masks MA1 are removed, and the dummy gate structures 130 are exposed after the planarization process is complete.

In some embodiments, the CESL 255 may be a dielectric layer including silicon nitride, silicon oxynitride or other suitable materials. In some embodiments, the ILD layer 252 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 255 and the ILD layer 252 can be formed using, for example, CVD, ALD or other suitable techniques.

Afterwards, the dummy gate structures 130 are etched back, so as to lower top surfaces of the dummy gate structures 130, and gate trenches GT1 are formed in each pair of the gate spacers 115. As a result, top surfaces of the remaining dummy gate structures 130 are higher than the topmost dielectric layers 135, and are lower than the bottommost semiconductor layers 202 (see FIG. 15B). Stated another way, top surfaces of the remaining dummy gate structures 130 are higher than bottom surface of the isolation layer 117, and are lower than top surface of the isolation layer 117.

The semiconductor layers 202 are then removed through the gate trenches GT1, such that the semiconductor layers 204 are suspended over the substrate 100. On the other hand, although the semiconductor layers 102 are made of a same material as the semiconductor layers 202, the semiconductor layers 102 are protected by the remaining dummy gate structures 130 during the removal of the semiconductor layers 202. In some embodiments, the semiconductor layers 202 may be removed using suitable etching process. In some embodiments, the semiconductor layers 202 can also be referred to as sacrificial layers.

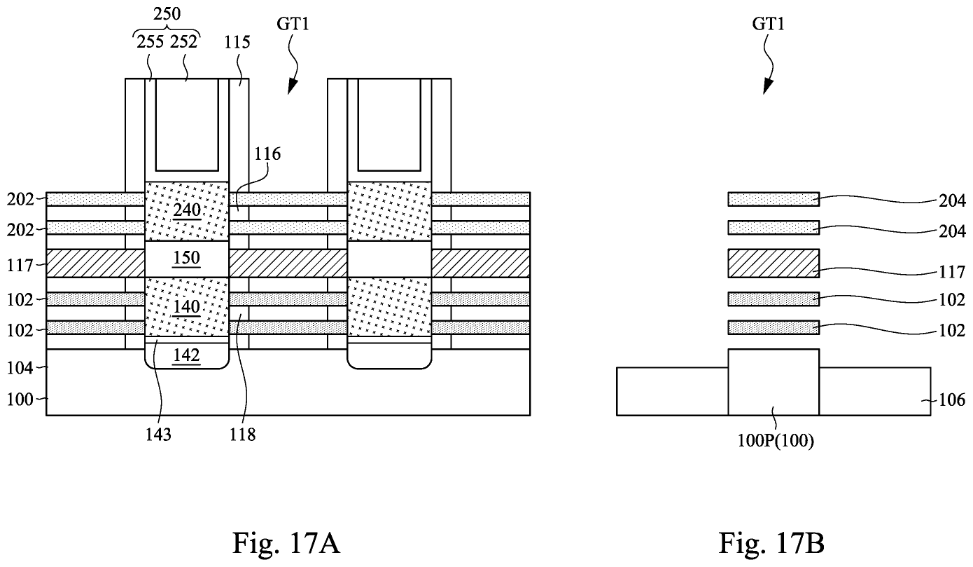

Reference is made to FIGS. 17A and 17B. The remaining dummy gate structures 130 are removed through the gate trenches GT1, so as to expose the dielectric layers 135. Then, the dielectric layers 135 are removed through the gate trenches GT1, such that the semiconductor layers 102 are suspended over the substrate 100. In some embodiments, the dielectric layers 135 may be removed using suitable etching process. In some embodiments, the semiconductor layers 202 may be removed using a first etchant, and the dielectric layers 135 may be removed using a second etchant that is different from the first etchant. In some embodiments, the dielectric layers 135 can also be referred to as sacrificial layers.

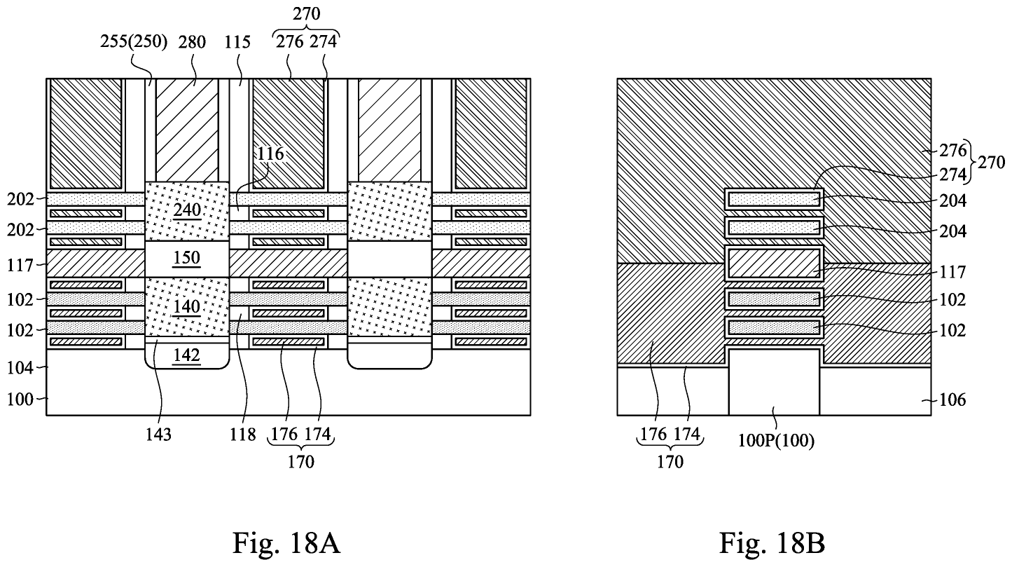

Reference is made to FIGS. 18A and 18B. Gate dielectric layers 174 and 274 are formed wrapping around the semiconductor layers 102 and 204, respectively. In some embodiments, the gate dielectric layers 174 and 274 may be formed using a same deposition process. In some embodiments, interfacial layers (not shown) may be formed over the semiconductor layers 102 and 204 prior to forming the gate dielectric layers 174 and 274. In the cross-sectional view of FIG. 18B, a dielectric layer made of a same material as the gate dielectric layers 174 and 274 may wrap around the isolation layer 117.

Then, gate electrodes 176 are formed over the gate dielectric layers 174. The gate electrodes 176 are then etched back, such that the remaining gate electrodes 176 are at the lower portion of the gate trenches GT1. Accordingly, first metal gate structures 170 are formed. In greater detail, the first metal gate structures 170 are formed in bottom portions of the gate trenches GT1, such that the first metal gate structures 170 may wrap around the respective semiconductor layers 102. In some embodiments, each of the first metal gate structures 170 may include the gate dielectric layer 174 and the gate electrode 176 over the gate dielectric layer 174.

Gate electrodes 276 are formed in the gate trenches GT1 and over the first metal gate structures 170. Accordingly, second metal gate structures 270 are formed. In greater detail, the second metal gate structures 270 are formed in upper portions of the gate trenches GT1 and above the first metal gate structures 170, such that the second metal gate structures 270 may wrap around the respective semiconductor layers 204. In some embodiments, each of the second metal gate structures 270 may include the gate dielectric layer 274 and the gate electrode 276 over the gate dielectric layer 274.

In some embodiments, the interfacial layers may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 and 276 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s). In some embodiments, the gate electrodes 176 may include n-type work function metal layer, while the gate electrodes 276 may include p-type work function metal layer.

After the metal gate structures 170 and 270 are formed, source/drain contacts 280 are formed in the isolation structures 250 and in contact with the second source/drain epitaxy structures 240, respectively. In some embodiments, the source/drain contacts 280 may be formed by, for example, etching the isolation structures 250 to form openings in the isolation structures 250 that expose the second source/drain epitaxy structures 240, filling the openings with conductive material(s), and then performing a planarization process, such as CMP, to remove excess conductive material(s). In some embodiments, each of the source/drain contacts 280 may include a diffusion barrier layer and a contact plug over the diffusion barrier layer. The diffusion barrier layer may include tantalum-based or titanium-based material, such as tantalum nitride (TaN), titanium nitride (TiN), titanium oxide (TiO), titanium (Ti), or the like. The contact plug may include tungsten (W), copper (Cu), aluminum (Al), ruthenium (Ru), cobalt (Co), molybdenum (Mo), nickel (Ni), or other suitable conductive material.

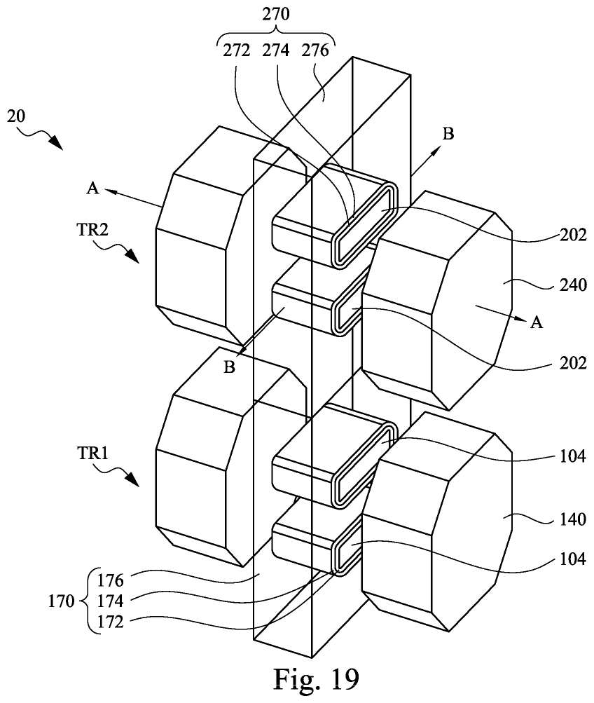

FIG. 19 is a perspective view of a semiconductor device in accordance with some embodiments of the present disclosure. In the present disclosure, a complementary FET (CFET) 20 is provided, and its manufacturing method will be disclosed in the following discussion. The first transistor TR1 includes first semiconductor channel layers 104 vertically stacked one above another, a first metal gate structure 170 wrapping around each of the first semiconductor channel layers 104, and first source/drain epitaxy structures 140 on opposite ends of each of the first semiconductor channel layers 104. Similarly, the second transistor TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. The CFET 20 of FIG. 19 is different from the CFET 10 of FIG. 1, in that the first transistor TR1 has a second conductivity type (e.g., p-type) and the second transistor TR2 has a first conductivity type (e.g., n-type) different from the second conductivity type. In some embodiments, the first transistor TR1 can be referred to as a P-FET, and the second transistor TR2 can be referred to as an N-FET. In some embodiments, the first semiconductor channel layers 102 may include material suitable for P-type device, such as silicon germanium (SiGe), while the second semiconductor channel layers 202 may include material suitable for N-type device, such as silicon (Si).

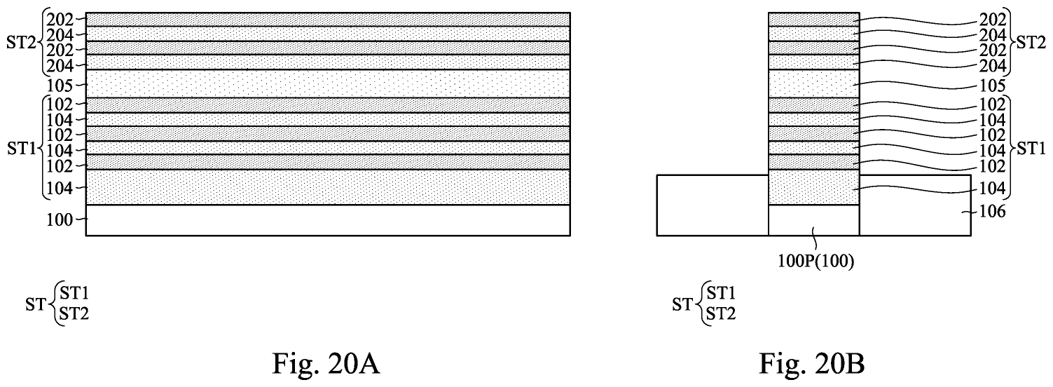

FIGS. 20A to 35B illustrate a method in various stages of forming a semiconductor device in accordance with some embodiments of the present disclosure. In greater detail, FIGS. 2A to 18B illustrate a method for forming a detailed structure of the CFET 10 of FIG. 1. It is noted that FIGS. 20A, 21A, 22A, 23A, 24A, 25A, 26A, 27A, 28A, 29A, 30A, 31A, 32A, 33A, 34A, and 35A include cross-sectional views the same as the cross-sectional view along line A-A of FIG. 19, and FIGS. 20B, 21B, 22B, 23B, 24B, 25B, 26B, 27B, 28B, 29B, 30B, 31B, 32B, 33B, 34B, and 35B include cross-sectional views the same as the cross-sectional view along line B-B of FIG. 19. It is noted that some elements discussed in FIGS. 20A to 35B may be similar to those described with respect to FIGS. 2A to 18B, such elements are labeled the same and relevant details will not be repeated for brevity.

Reference is made to FIGS. 2A and 2B. Shown there is a substrate 100. A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 50 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es).

A patterning process may be performed to the semiconductor stack ST and the substrate 100 to form a fin structure, as shown in FIG. 20B. In some embodiments, the patterning process may include forming a patterned photoresist layer over the stack ST, and then performing an etching process to remove unwanted portions of the semiconductor stack ST and the substrate 100 exposed by the patterned photoresist layer. The fin structure may include a remaining portion of the semiconductor stack ST and a semiconductor strip 100P protruding over the substrate 100. In some embodiments, the etching process may include wet etch, dry etch, or the like.

After the fin structure is formed, isolation structures 106 are formed over the substrate 100 and laterally surrounding the fin structure. In some embodiments, the isolation structures 106 may be in contact with sidewalls of the semiconductor strip 100P of the substrate 100, and may also be in contact with sidewalls of the bottommost semiconductor layer 104.

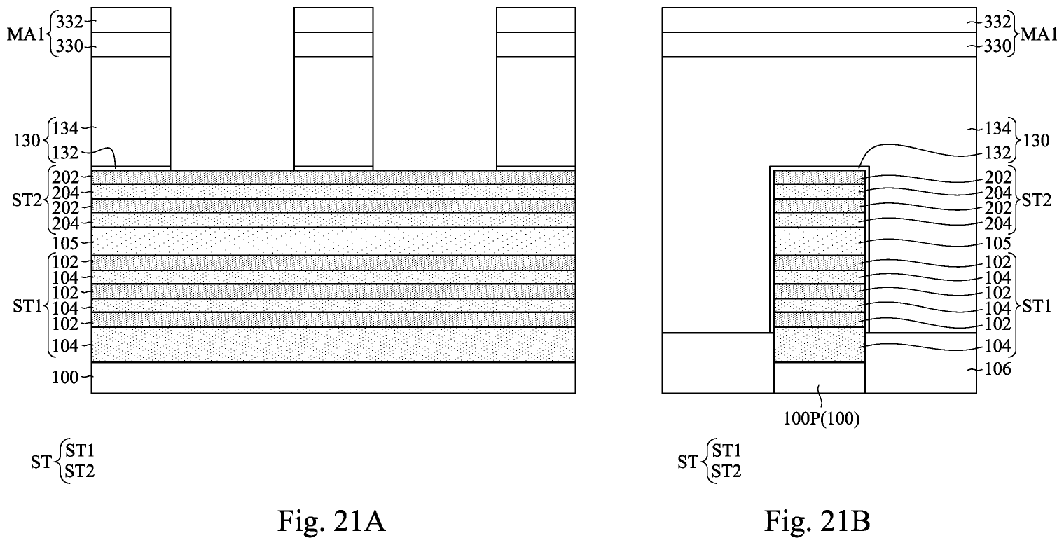

Reference is made to FIGS. 21A and 21B. Dummy gate structures 130 are formed over the substrate 100 and crossing the fin structure. In some embodiments, each of the dummy gate structures 130 includes a dummy gate dielectric 132 and a dummy gate electrode 134 over the dummy gate dielectric 132. Patterned masks MA1 are disposed over the dummy gate structures 130, respectively, in which each of the patterned masks MA1 includes a first hard mask 330 and a second hard mask 332 over the first hard mask 330.

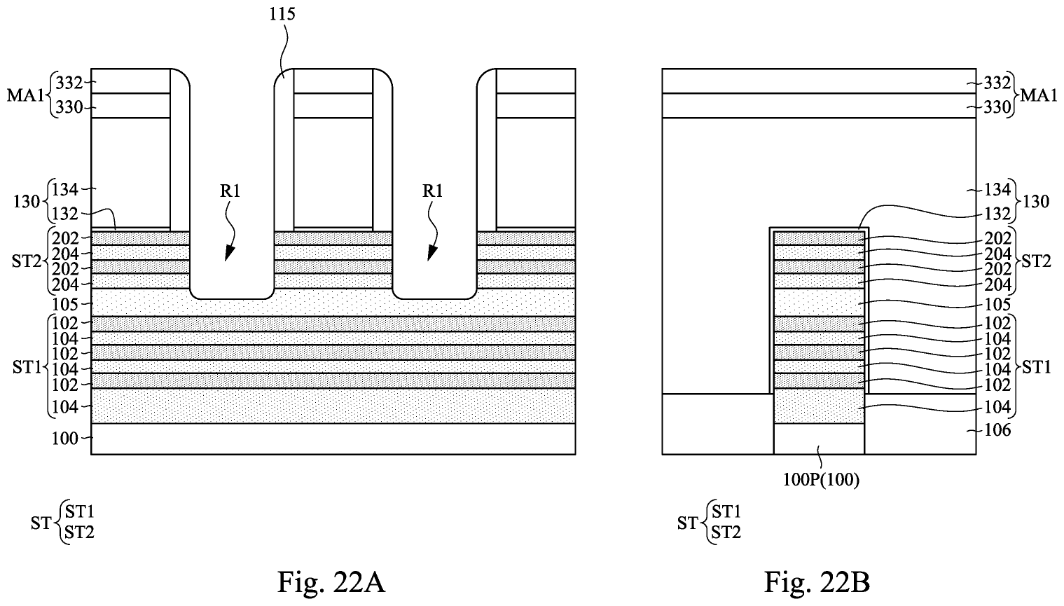

Reference is made to FIGS. 22A and 22B. Gate spacers 115 are formed on opposite sidewalls of each of the dummy gate structures 130. Afterwards, an etching process is performed, by using the gate spacers 115 and the patterned masks MA1 (or the dummy gate structures 130) as etch mask, to remove portions of the second stack ST2. In greater detail, the etching process removes portions of the semiconductor layers 202 and 204, so as to form recesses R1 in the second stack ST2.

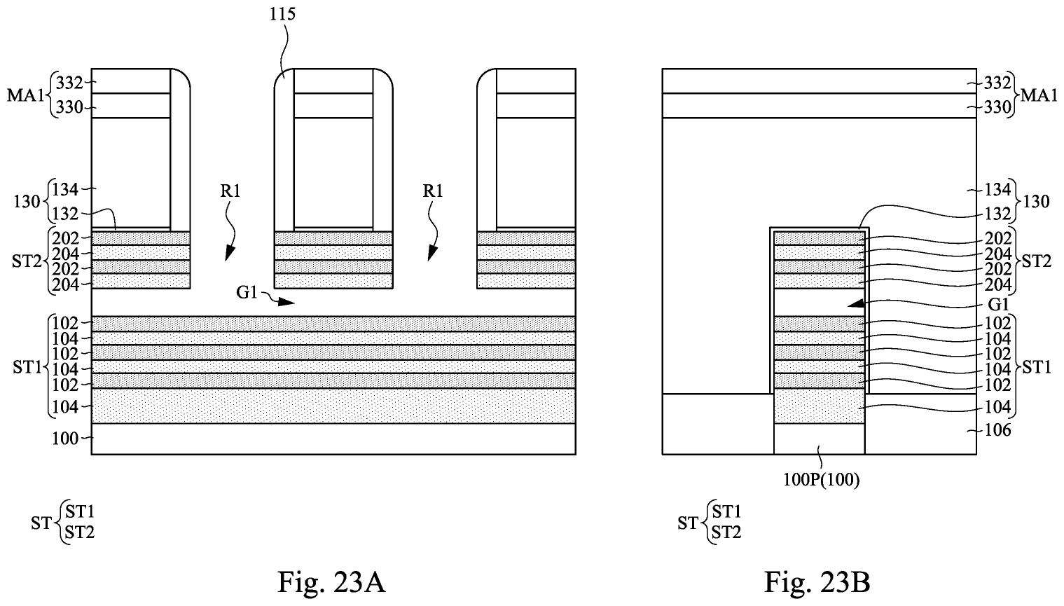

Reference is made to FIGS. 23A and 23B. An etching process is performed to remove the semiconductor layer 105 through the recesses R1. As a result, gaps G1 may be formed between the first stack ST1 and the second stack ST2. In greater detail, each of the gaps G1 is vertically between the topmost semiconductor layer 102 and the bottommost semiconductor layer 204.

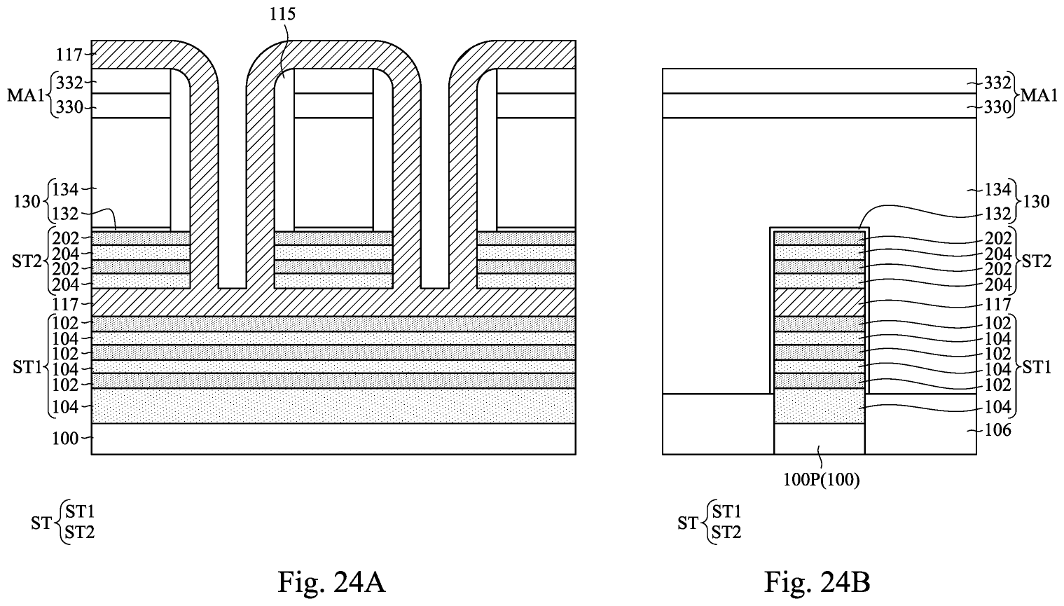

Reference is made to FIGS. 24A and 24B. An isolation layer 117 is deposited blanket over the substrate 100 and filling the gaps G1.

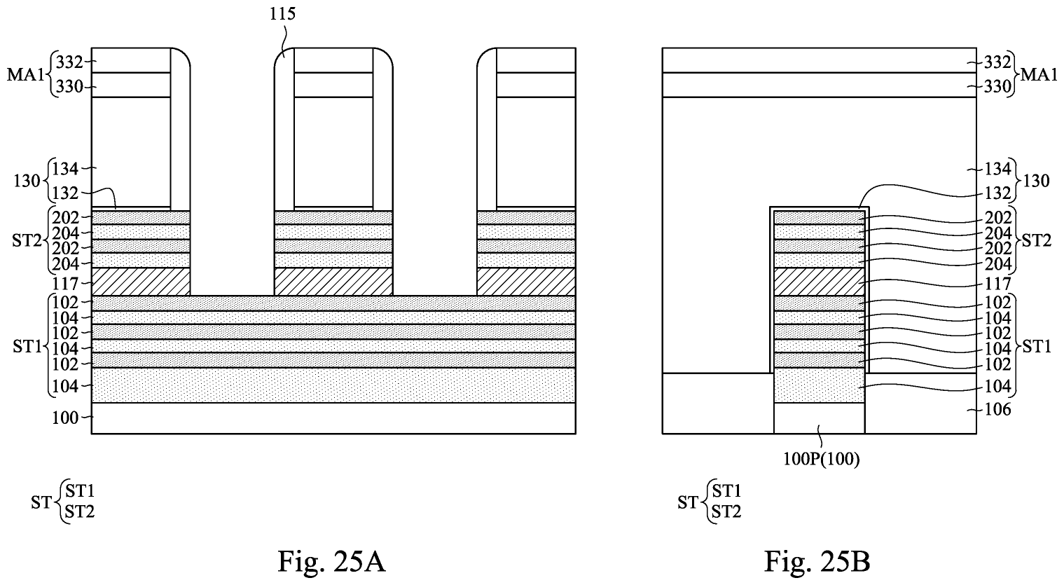

Reference is made to FIGS. 25A and 25B. An anisotropic etching process is performed to remove portions of the isolation layer 117 outside the gaps G1, and the remaining portions of the isolation layer 117 are present between the topmost semiconductor layer 102 and the bottommost semiconductor layer 204.

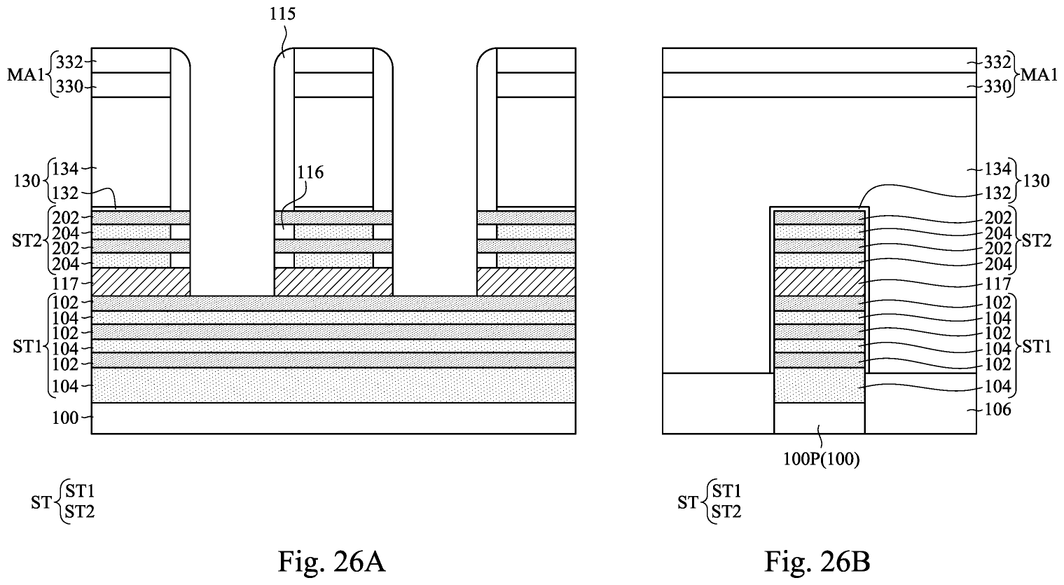

Reference is made to FIGS. 26A and 26B. The semiconductor layers 204 are laterally etched to form sidewall recesses. Then, inner spacers 116 are formed in the sidewall recesses on opposite ends of each of the semiconductor layers 204.

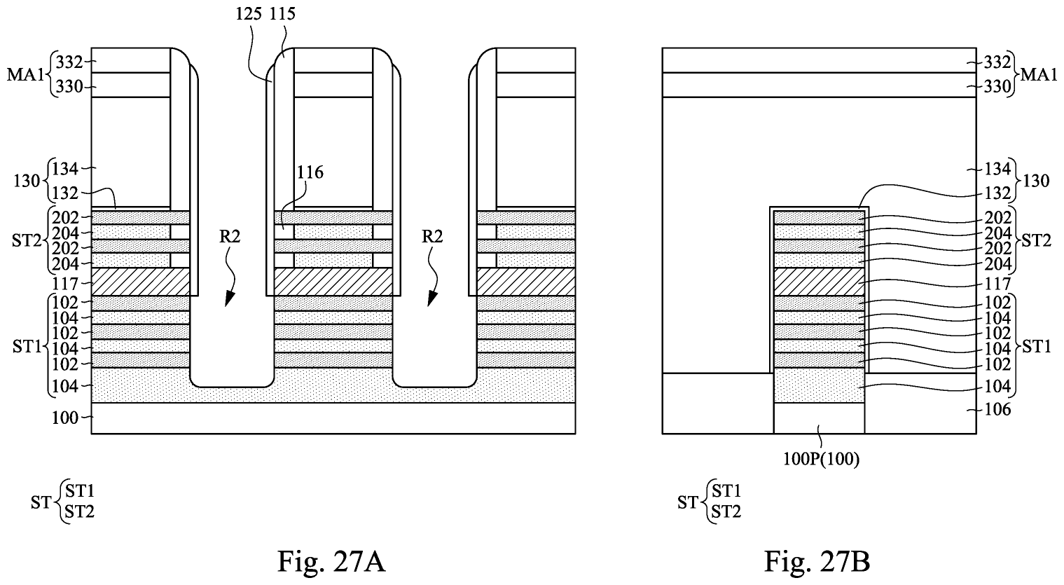

Reference is made to FIGS. 27A and 27B. Liners 125 are formed lining sidewall surfaces of the semiconductor layers 202. Then, an etching process is performed, by using the liners 125, the gate spacers 115, and the patterned masks MA1 (or the dummy gate structures 130) as etch mask, to remove portions of the first stack ST1. In greater detail, the etching process removes portions of the semiconductor layers 102 and 104, so as to form recesses R2 in the first stack ST1.

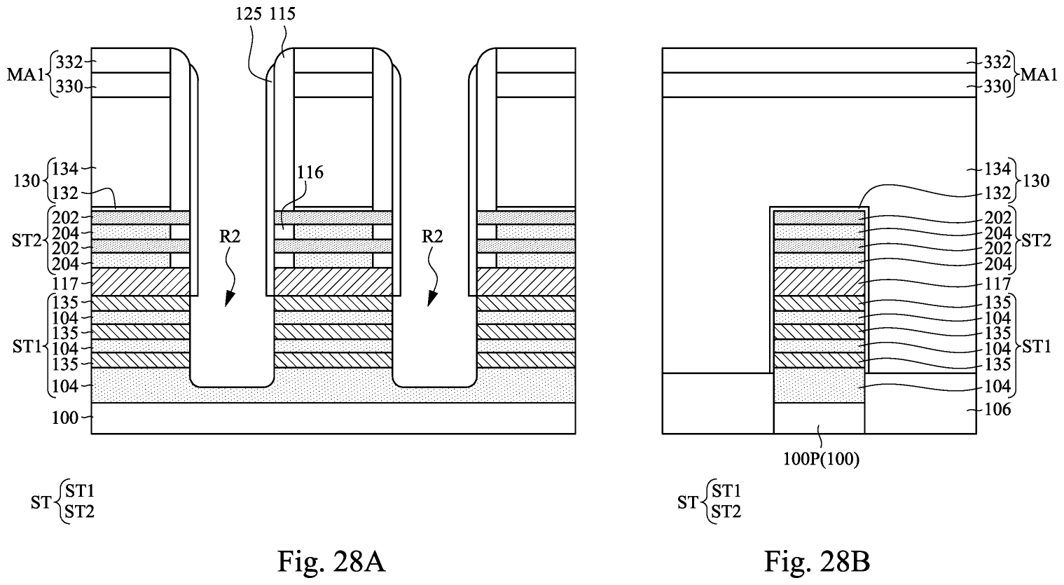

Reference is made to FIGS. 28A and 28B. The semiconductor layers 102 are replaced with dielectric layers 135. In some embodiments, the dielectric layers 135 may include oxide, such as silicon oxide (SiO₂). The dielectric layers 135 may include different dielectric materials than the isolation layer 117 to provide sufficient etching selectivity. The dielectric layers 135 may be formed by, for example, performing an etching process through the recesses R2 to remove the semiconductor layers 102 and to form gaps over and under each of the semiconductor layers 104, depositing a dielectric material within the recesses R2 and filling the gaps, and then performing another etching process to remove the dielectric material outside the gaps, leaving the remaining portions of the dielectric material within the gaps as the dielectric layers 135.

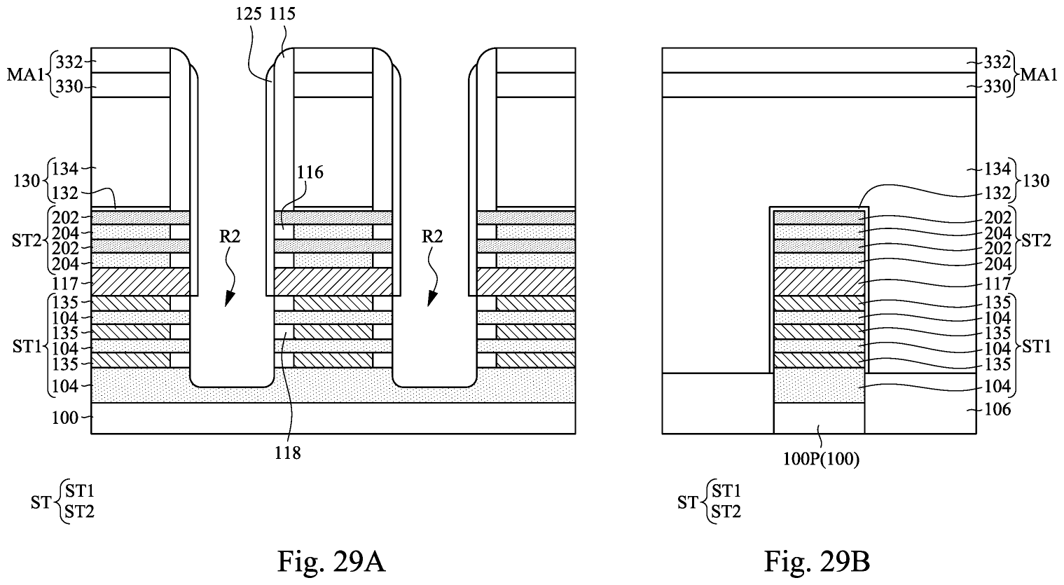

Reference is made to FIGS. 29A and 29B. The dielectric layers 135 are laterally etched to form sidewall recesses. Then, inner spacers 118 are formed in the sidewall recesses on opposite ends of each of the dielectric layers 135.

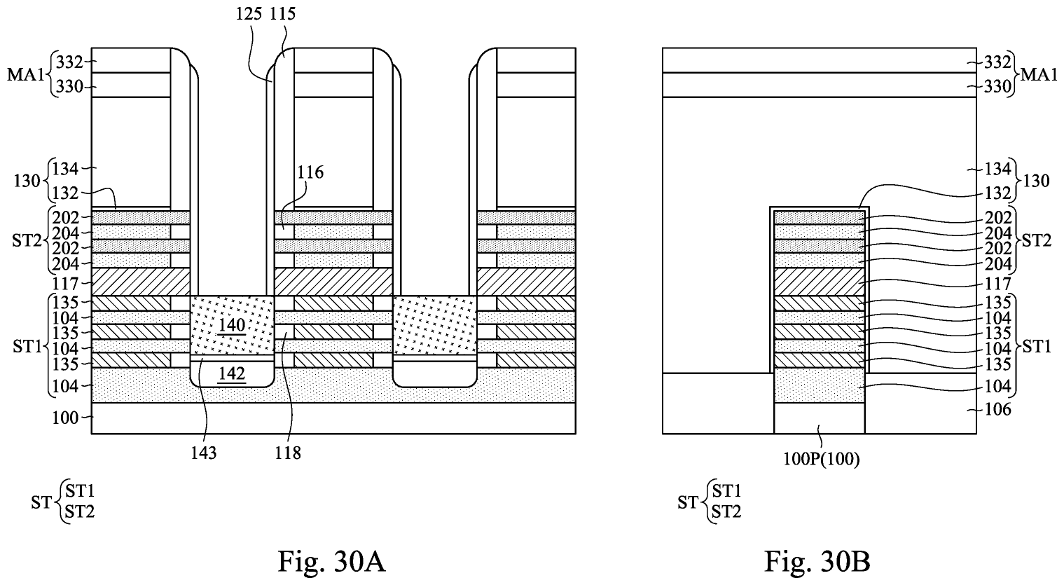

Reference is made to FIGS. 30A and 30B. Epitaxy layers 142 are formed at bottoms of the recesses R2, dielectric layers 143 are formed over the epitaxy layers 142, and then first source/drain epitaxy structures 140 are formed over the dielectric layers 143 and in contact with opposite ends of the semiconductor layers 104. In some embodiments, the first source/drain epitaxy structures 140 may include SiB, SiGe, or combination of SiB and SiGe. In some embodiments, an implantation process may be performed to the first source/drain epitaxy structures 140. For example, the implantation process may include p-type dopants, such as boron (B), gallium (Ga), indium (In), aluminium (Al), or the like, such that the first source/drain epitaxy structures 140 are p-type epitaxy structures.

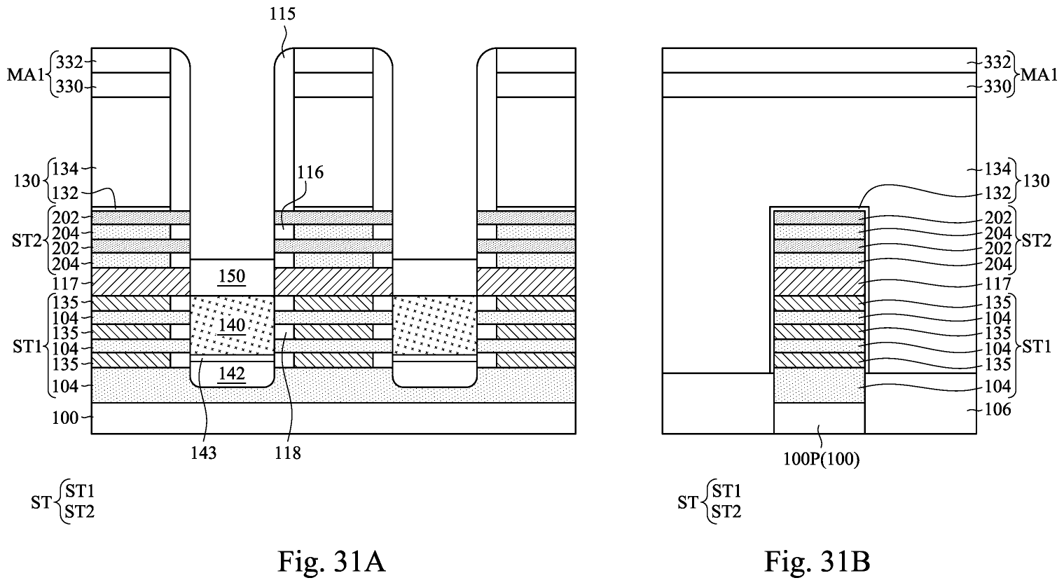

Reference is made to FIGS. 31A and 31B. The liners 125 are removed by using suitable etching process, such that sidewalls of the semiconductor layers 202 are exposed. Then, isolation structures 150 are formed over the first source/drain epitaxy structures 140, respectively.

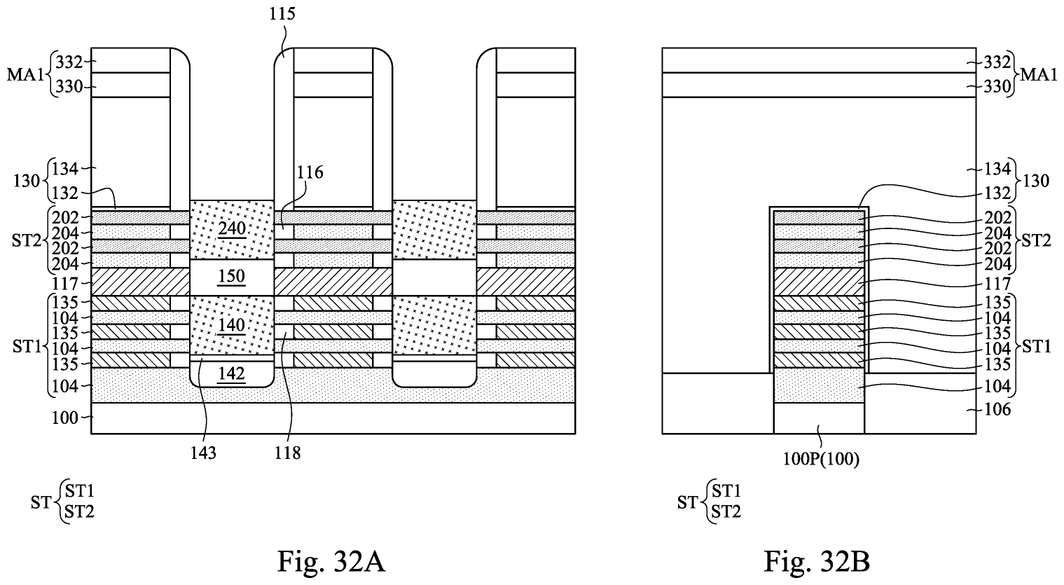

Reference is made to FIGS. 32A and 32B. Second source/drain epitaxy structures 240 are formed on opposite ends of each of the semiconductor layers 202. In some embodiments, the second source/drain epitaxy structures 240 may include SiAs, SiP, or combination of SiAs and SiP. In some embodiments, an implantation process may be performed to the second source/drain epitaxy structures 240. For example, the implantation process may include n-type dopants, such as phosphorus (P), arsenic (As), or antimony (Sb), or the like, such that the second source/drain epitaxy structures 240 are n-type epitaxy structures.

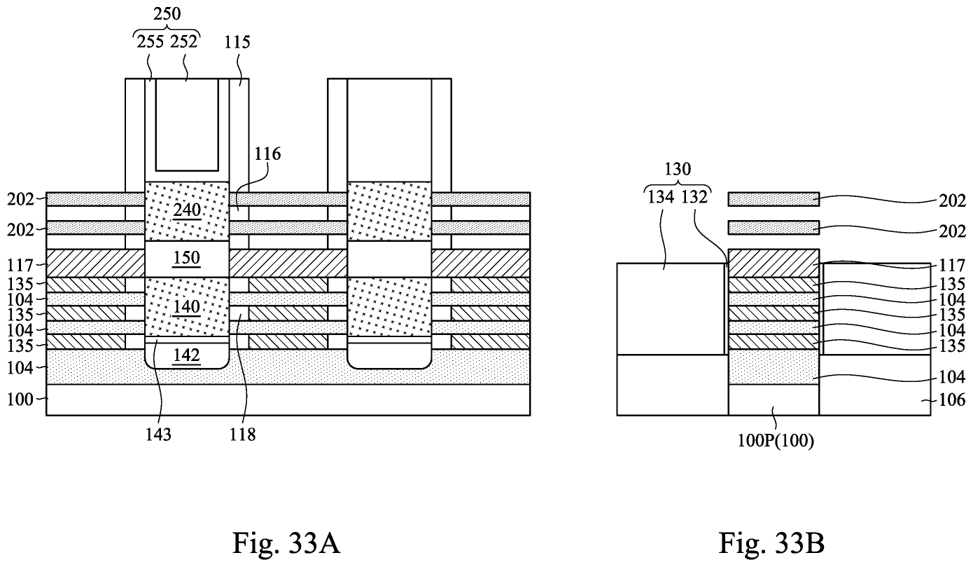

Reference is made to FIGS. 33A and 33B. Isolation structures 250 are formed over the second source/drain epitaxy structures 240, respectively, in which each of the isolation structures 250 includes a contact etch stop layer (CESL) 255 and an interlayer dielectric (ILD) layer 252 over the CESL 255. The isolation structures 250 may be formed by, for example, depositing dielectric material(s) over the second source/drain epitaxy structures 240, and then performing a planarization process, such as CMP, to remove excess dielectric material(s). In some embodiments, during the planarization process, the patterned masks MA1 are removed, and the dummy gate structures 130 are exposed after the planarization process is complete.

Afterwards, the dummy gate structures 130 are etched back, so as to lower top surfaces of the dummy gate structures 130, and gate trenches GT1 are formed in each pair of the gate spacers 115. As a result, top surfaces of the remaining dummy gate structures 130 are higher than the topmost dielectric layers 135, and may be lower than the bottommost semiconductor layers 202 (see FIG. 33B).

The semiconductor layers 204 are removed through the gate trenches GT1, such that the semiconductor layers 202 are suspended over the substrate 100. On the other hand, although the semiconductor layers 104 are made of a same material as the semiconductor layers 204, the semiconductor layers 104 are protected by the remaining dummy gate structures 130 during the removal of the semiconductor layers 204. In some embodiments, the semiconductor layers 204 may be removed using suitable etching process.

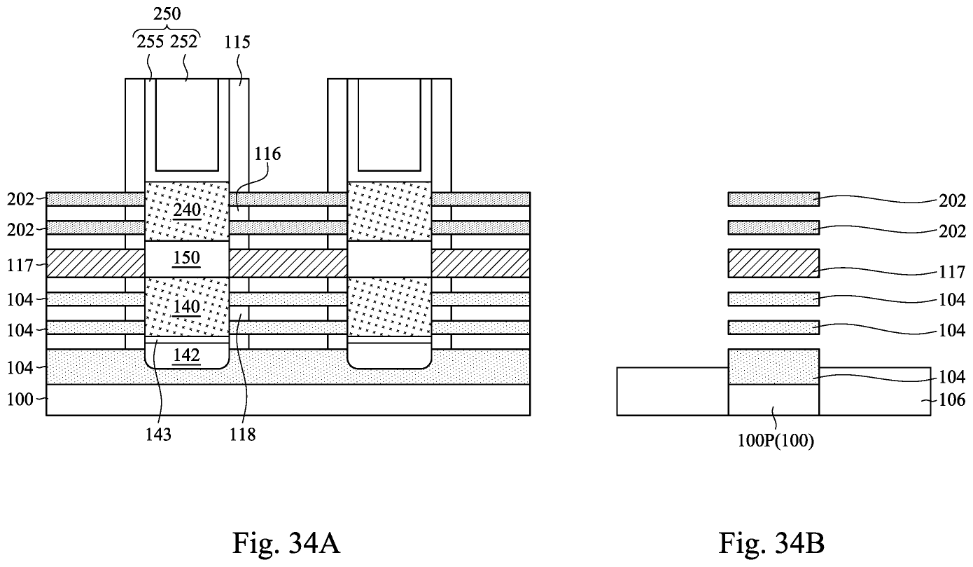

Reference is made to FIGS. 34A and 34B. The remaining dummy gate structures 130 are removed through the gate trenches GT1, so as to expose the dielectric layers 135. Then, the dielectric layers 135 are removed through the gate trenches GT1, such that the semiconductor layers 104 are suspended over the substrate 100. In some embodiments, the semiconductor layers 204 may be removed using a first etchant, and the dielectric layers 135 may be removed using a second etchant that is different from the first etchant.

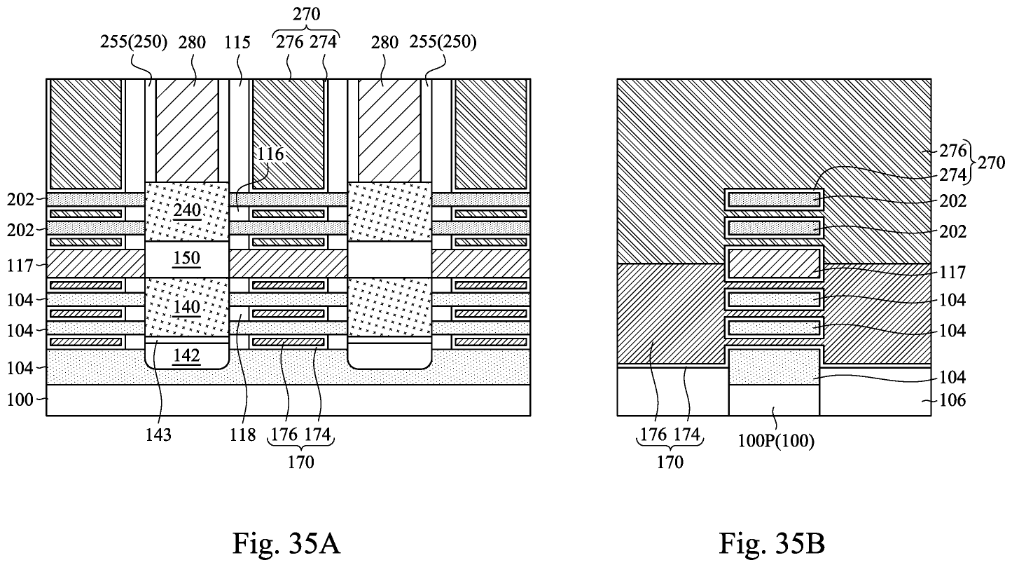

Reference is made to FIGS. 35A and 35B. Gate dielectric layers 174 and 274 are formed wrapping around the semiconductor layers 102 and 204, respectively. Then, gate electrodes 176 are formed over the gate dielectric layers 174. The gate electrodes 176 are then etched back, such that the remaining gate electrodes 176 are at the lower portion of the gate trenches GT1. Accordingly, first metal gate structures 170 are formed. In greater detail, the first metal gate structures 170 are formed in bottom portions of the gate trenches GT1, such that the first metal gate structures 170 may wrap around the respective semiconductor layers 102. In some embodiments, each of the first metal gate structures 170 may include the gate dielectric layer 174 and the gate electrode 176 over the gate dielectric layer 174.

Gate electrodes 276 are formed in the gate trenches GT1 and over the first metal gate structures 170. Accordingly, second metal gate structures 270 are formed. In greater detail, the second metal gate structures 270 are formed in upper portions of the gate trenches GT1 and above the first metal gate structures 170, such that the second metal gate structures 270 may wrap around the respective semiconductor layers 204. In some embodiments, each of the second metal gate structures 270 may include the gate dielectric layer 274 and the gate electrode 276 over the gate dielectric layer 274. In some embodiments, the gate electrodes 176 may include p-type work function metal layer, while the gate electrodes 276 may include n-type work function metal layer.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a CFET and a method for forming the CFET, which includes a first transistor and a second transistor above the first transistor. The first transistor and the second transistor include different conductivity types. In some embodiments, the first transistor is an n-type device and the second transistor is a p-type device. In other embodiments, the first transistor is a p-type device and the second transistor is an n-type device. The n-type device includes silicon channel layer, and the p-type device includes silicon germanium channel layer. Such configuration may be beneficial for Vt tuning feasibility, and will improve the device performance.

In some embodiments of the present disclosure, a method includes forming a first stack of alternating first semiconductor layers and first sacrificial layers over a substrate; forming a second stack of alternating second semiconductor layers and second sacrificial layers over the first stack, wherein the first semiconductor layers and the second semiconductor layers are made of different materials; replacing the first sacrificial layers with third sacrificial layers; removing the second sacrificial layers, such that the second semiconductor layers are suspended over the substrate; after removing the second sacrificial layers, removing the third sacrificial layers, such that the first semiconductor layers are suspended over the substrate; forming a first metal gate structure wrapping around the first semiconductor layers; and forming a second metal gate structure wrapping around the second semiconductor layers.

In some embodiments, the method further includes forming liners covering opposite ends of the second semiconductor layers prior to replacing the first sacrificial layers with the third sacrificial layers; and removing the liners after replacing the first sacrificial layers with the third sacrificial layers.

In some embodiments, the method further includes forming first source/drain epitaxy structures on opposite ends of the first semiconductor layers prior to removing the liners; and forming second source/drain epitaxy structures on opposite ends of the second semiconductor layers after removing the liners.

In some embodiments, the first sacrificial layers are made of semiconductor materials, while the third sacrificial layers are made of dielectric materials.

In some embodiments, the method further includes forming a dummy gate structure over the second stack; and etching back the dummy gate structure to lower a top surface of the dummy gate structure, wherein a remaining portion of the dummy gate structure protects the third sacrificial layers during removing the second sacrificial layers.

In some embodiments, the method further includes removing the remaining portion of the dummy gate structure prior to removing the third sacrificial layers.

In some embodiments, the first semiconductor layers and the second sacrificial layers are made of a first semiconductor material, and the second semiconductor layers and the first sacrificial layers are made of a second semiconductor material different from the first semiconductor material.

In some embodiments of the present disclosure, a method includes forming a semiconductor stack over a substrate, the semiconductor stack comprising a first stack of alternating first semiconductor layers and first sacrificial layers, a second stack of alternating second semiconductor layers and second sacrificial layers over the first stack, and a third semiconductor layer between the first stack and the second stack; forming a dummy gate structure over the semiconductor stack; etching the second stack by using the dummy gate structure as an etch mask to form first recesses in the second stack, wherein the first recesses expose the third semiconductor layer; replacing the third semiconductor layer with an isolation layer; after replacing the third semiconductor layer with the isolation layer, etching the first stack through the first recesses to form second recesses in the first stack; removing the dummy gate structure; removing the first sacrificial layers and the second sacrificial layers; forming a first metal gate structure wrapping around the first semiconductor layers; and forming a second metal gate structure wrapping around the second semiconductor layers.

In some embodiments, the method further includes replacing the first sacrificial layers with third sacrificial layers; and removing the third sacrificial layers prior to forming the first metal gate structure.

In some embodiments, the method further includes laterally etching the second sacrificial layers; forming first inner spacers on opposite ends of each of the second sacrificial layers; after forming the first inner spacers, laterally etching the third sacrificial layers; and forming second inner spacers on opposite ends of each of the third sacrificial layers.

In some embodiments, the method further includes forming liners covering sidewalls of the second semiconductor layers and the first inner spacers prior to forming the second inner spacers.

In some embodiments, the first semiconductor layers and the second semiconductor layers are made of different materials.

In some embodiments, the method further includes forming first source/drain epitaxy structures on opposite ends of each of the first semiconductor layers; and after forming the first source/drain epitaxy structures, forming second source/drain epitaxy structures on opposite ends of each of the second semiconductor layers.

In some embodiments, the method further includes forming isolation structures over the first source/drain epitaxy structures prior to forming the second source/drain epitaxy structures.

In some embodiments, the first semiconductor layers and the second sacrificial layers are made of silicon, while the second semiconductor layers and the first sacrificial layers are made of silicon germanium.

In some embodiments, the first semiconductor layers and the second sacrificial layers are made of a silicon germanium, while the second semiconductor layers and the first sacrificial layers are made of silicon.

In some embodiments of the present disclosure, a semiconductor device includes a first transistor over a substrate and a second transistor above the first transistor. The first transistor includes a first semiconductor channel layer made of a first semiconductor material, a first gate structure wrapping around the first semiconductor channel layer, and first source/drain epitaxy structures on opposite ends of the first semiconductor channel layer. The second transistor includes a second semiconductor channel layer made of a second semiconductor material different from the first semiconductor material, a second gate structure wrapping around the second semiconductor channel layer, and second source/drain epitaxy structures on opposite ends of the second semiconductor channel layer.

In some embodiments, the semiconductor device further includes dielectric layers below the first source/drain epitaxy structures. Epitaxial layers are below the dielectric layers and disposed in the substrate.

In some embodiments, the first semiconductor material is made of silicon and the first source/drain epitaxy structures are made of SiAs, SiP, or combination thereof. The second semiconductor material is made of silicon germanium and the second source/drain epitaxy structures are made of SiB, SiGe, or combination thereof.

In some embodiments, the first semiconductor material is made of silicon germanium and the first source/drain epitaxy structures are made of SiB, SiGe, or combination thereof. The second semiconductor material is made of silicon and the second source/drain epitaxy structures are made of SiAs, SiP, or combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first stack of alternating first semiconductor layers and first sacrificial layers over a substrate;
forming a second stack of alternating second semiconductor layers and second sacrificial layers over the first stack, wherein the first semiconductor layers and the second semiconductor layers are made of different materials;
replacing the first sacrificial layers with third sacrificial layers;
removing the second sacrificial layers, such that the second semiconductor layers are suspended over the substrate;
after removing the second sacrificial layers, removing the third sacrificial layers, such that the first semiconductor layers are suspended over the substrate;
forming a first metal gate structure wrapping around the first semiconductor layers; and
forming a second metal gate structure wrapping around the second semiconductor layers.

2. The method of claim 1, further comprising:
forming liners covering opposite ends of the second semiconductor layers prior to replacing the first sacrificial layers with the third sacrificial layers; and
removing the liners after replacing the first sacrificial layers with the third sacrificial layers.

3. The method of claim 2, further comprising:
forming first source/drain epitaxy structures on opposite ends of the first semiconductor layers prior to removing the liners; and
forming second source/drain epitaxy structures on opposite ends of the second semiconductor layers after removing the liners.

4. The method of claim 1, wherein the first sacrificial layers are made of semiconductor materials, while the third sacrificial layers are made of dielectric materials.

5. The method of claim 1, further comprising:
forming a dummy gate structure over the second stack; and
etching back the dummy gate structure to lower a top surface of the dummy gate structure, wherein a remaining portion of the dummy gate structure protects the third sacrificial layers during removing the second sacrificial layers.

6. The method of claim 5, further comprising removing the remaining portion of the dummy gate structure prior to removing the third sacrificial layers.

7. The method of claim 1, wherein the first semiconductor layers and the second sacrificial layers are made of a first semiconductor material, and the second semiconductor layers and the first sacrificial layers are made of a second semiconductor material different from the first semiconductor material.

8. A method, comprising:
forming a semiconductor stack over a substrate, the semiconductor stack comprising:
a first stack of alternating first semiconductor layers and first sacrificial layers;
a second stack of alternating second semiconductor layers and second sacrificial layers over the first stack; and
a third semiconductor layer between the first stack and the second stack;
forming a dummy gate structure over the semiconductor stack;
etching the second stack by using the dummy gate structure as an etch mask to form first recesses in the second stack, wherein the first recesses expose the third semiconductor layer;
replacing the third semiconductor layer with an isolation layer;
after replacing the third semiconductor layer with the isolation layer, etching the first stack through the first recesses to form second recesses in the first stack;
removing the dummy gate structure;
removing the first sacrificial layers and the second sacrificial layers;
forming a first metal gate structure wrapping around the first semiconductor layers; and
forming a second metal gate structure wrapping around the second semiconductor layers.

9. The method of claim 8, further comprising:
replacing the first sacrificial layers with third sacrificial layers; and
removing the third sacrificial layers prior to forming the first metal gate structure.

10. The method of claim 9, further comprising:
laterally etching the second sacrificial layers;
forming first inner spacers on opposite ends of each of the second sacrificial layers;
after forming the first inner spacers, laterally etching the third sacrificial layers; and
forming second inner spacers on opposite ends of each of the third sacrificial layers.

11. The method of claim 10, further comprising forming liners covering sidewalls of the second semiconductor layers and the first inner spacers prior to forming the second inner spacers.

12. The method of claim 8, wherein the first semiconductor layers and the second semiconductor layers are made of different materials.

13. The method of claim 8, further comprising:
forming first source/drain epitaxy structures on opposite ends of each of the first semiconductor layers; and
after forming the first source/drain epitaxy structures, forming second source/drain epitaxy structures on opposite ends of each of the second semiconductor layers.

14. The method of claim 13, further comprising forming isolation structures over the first source/drain epitaxy structures prior to forming the second source/drain epitaxy structures.

15. The method of claim 8, wherein the first semiconductor layers and the second sacrificial layers are made of silicon, while the second semiconductor layers and the first sacrificial layers are made of silicon germanium.

16. The method of claim 8, wherein the first semiconductor layers and the second sacrificial layers are made of silicon germanium, while the second semiconductor layers and the first sacrificial layers are made of silicon.

17. A semiconductor device, comprising:
a first transistor over a substrate, comprising:
a first semiconductor channel layer made of a first semiconductor material;
a first gate structure wrapping around the first semiconductor channel layer; and
first source/drain epitaxy structures on opposite ends of the first semiconductor channel layer; and
a second transistor above the first transistor, comprising:
a second semiconductor channel layer made of a second semiconductor material different from the first semiconductor material;
a second gate structure wrapping around the second semiconductor channel layer; and
second source/drain epitaxy structures on opposite ends of the second semiconductor channel layer.

18. The semiconductor device of claim 17, further comprising:
dielectric layers below the first source/drain epitaxy structures; and
epitaxial layers below the dielectric layers and disposed in the substrate.

19. The semiconductor device of claim 17, wherein,
the first semiconductor material is made of silicon and the first source/drain epitaxy structures are made of SiAs, SiP, or combination thereof; and
the second semiconductor material is made of silicon germanium and the second source/drain epitaxy structures are made of SiB, SiGe, or combination thereof.

20. The semiconductor device of claim 17, wherein,
the first semiconductor material is made of silicon germanium and the first source/drain epitaxy structures are made of SiB, SiGe, or combination thereof; and
the second semiconductor material is made of silicon and the second source/drain epitaxy structures are made of SiAs, SiP, or combination thereof.
